(19) United States
(12) Patent Application Publication
(10) Pub. No.: US 2025/0323048 A1
(43) Pub. Date: Oct. 16, 2025

(54) METHOD OF PROCESSING WAFER

(71) Applicant: DISCO CORPORATION, Tokyo (JP)

(72) Inventor: Kokichi MINATO, Tokyo (JP)

(21) Appl. No.: 19/169,331

(22) Filed: Apr. 3, 2025

(30) Foreign Application Priority Data
Apr. 10, 2024 (JP) 2024-063241

(51) Int. Cl. H01L 21/304; H01L 21/306

(52) U.S. Cl. CPC H01L 21/304; H01L 21/30625

(57) ABSTRACT

A method of processing a wafer for solving problems where a chamfered portion is not completely removed from an outer periphery of the wafer. This method includes: preparing a processing apparatus, including a chuck table, cutting means including a rotatable cutting blade, and polishing means including a rotatable polishing blade; holding the wafer on the chuck table; removing the chamfered portion by rotating the chuck table, with the cutting blade being positioned on the outer peripheral surplus region of the wafer, and with the cutting blade rotating; and polishing a cut surface, from which the chamfered portion has been removed, into a mirror surface by rotating the chuck table, with the polishing blade being positioned on the outer periphery of the wafer that is held on the chuck table in a state where the chamfered portion has been removed, and with the polishing blade rotating.

### BACKGROUND OF THE INVENTION

### 1. Field of the Invention

The present invention relates to a method of processing a wafer.

### 2. Description of the Related Art

A wafer, on the front surface of which a plurality of devices, such as ICs and LSIs, are formed in a state of being demarcated by division lines, is ground on a rear surface thereof by a grinding apparatus to a desired thickness, and is then divided into individual device chips by a dicing apparatus. The device chips are used in electronic appliances, such as portable phones and personal computers.

A chamfer portion is formed on the outer periphery of the wafer, and when the rear surface of the wafer is thinned by grinding, this chamfered portion may become sharp like a knife edge, which may harm an operator or cause the wafer to crack from the outer periphery in an inward direction, thereby damaging the device.

This problem could occur not only to a single wafer but also to a bonded wafer formed by bonding two wafers. In the bonded wafer, on each of the wafers to be bonded, a pattern generated by a surface activation method or the like is formed, for example.

To solve the above problem, the applicant of the present invention has proposed a technique in which a focusing point of a laser beam, having a wavelength transmissive to the wafer, is positioned on the inner side of the chamfered portion and the laser beam is applied thereto, before grinding the rear surface of the wafer, so that a modified ring-shaped layer is formed inside the wafer, whereby the chamfered portion is removed (see JP 2020-88187 A).

### SUMMARY OF THE INVENTION

In some cases of removing the chamfered portion starting from the modified layer, however, the chamfered portion may not be completely removed from the outer periphery of the wafer, and a small amount of this remaining portion may fall and become a source of contamination in subsequent steps, or may cause chipping of the device chips when the wafer is diced into individual device chips.

With the foregoing in view, it is an object of the present invention to provide a method of processing a wafer for solving such problems where the chamfered portion is not completely removed from the outer periphery of the wafer, and a small amount of this remaining portion falls and becomes a source of contamination in subsequent steps, or the remaining portion causes chipping of device chips when the wafer is diced into individual device chips.

To solve the abovementioned technical problems, the present invention provides a method of processing a wafer having an effective region including a device region, in which a plurality of devices are demarcated by division lines, and an outer peripheral surplus region, in which a chamfered portion surrounding the effective region is formed. This method includes: a preparation step of preparing a processing apparatus, which includes a chuck table configured to hold a wafer; cutting means including a rotatable cutting blade configured to cut the chamfered portion of the wafer held on the chuck table, and polishing means including a rotatable polishing blade configured to polish a surface from which the chamfered portion has been removed; a wafer holding step of holding the wafer on the chuck table; a chamfered portion removing step of removing the chamfered portion by rotating the chuck table, with the cutting blade being positioned on the outer peripheral surplus region of the wafer that is held on the chuck table, and with the cutting blade rotating; a mirror surface processing step of polishing a cut surface, from which the chamfered portion has been removed, into a mirror surface by rotating the chuck table, with the polishing blade being positioned on the outer periphery of the wafer that is held on the chuck table, in a state where the chamfer portion has been removed, and with the polishing blade rotating.

In the mirror surface processing step, it is preferable that water or slurry is supplied to polish the cut surface. It is also preferable that the wafer is a bonded wafer generated by bonding a surface, on which the effective region of a first wafer has been formed, with a second wafer, and in the wafer holding step, the second wafer side is held on the chuck table, and the chamfered portion removing step and the mirror surface processing step are performed on the rear surface of the first wafer of the wafer held on the chuck table.

The method of processing a wafer of the present invention includes: a preparation step of preparing a processing apparatus, which includes: a chuck table configured to hold a wafer, cutting means including a rotatable cutting blade configured to cut the chamfered portion of the wafer held on the chuck table, and polishing means including a rotatable polishing blade configured to polish a surface from which the chamfered portion has been removed; a wafer holding step of holding the wafer on the chuck table; a chamfered portion removing step of removing the chamfered portion by rotating the chuck table, with the cutting blade being positioned on the outer peripheral surplus region of the wafer that is held on the chuck table, and with the cutting blade rotating; and a mirror surface processing step of polishing a cut surface, from which the chamfered portion has been removed, into a mirror surface by rotating the chuck table, with the polishing blade being positioned on the outer periphery of the wafer that is held on the chuck table in a state where the chamfered portion has been removed, and with the polishing blade rotating. Since the chamfered portion is removed from the outer periphery of the wafer by the cutting means, and then the cut surface is polished into the mirror surface by the polishing means, the remaining portion is removed completely. Thereby such problems where the remaining portion falls and becomes a source of contamination in subsequent steps, or the remaining portion causes chipping of the device chips when the wafer is diced into individual chips, are solved.

### BRIEF DESCRIPTION OF THE DRAWINGS

FIG. 1 is a general perspective view of a processing apparatus according to the present embodiment;

FIG. 2 indicates a partially enlarged perspective view and an exploded perspective view illustrating processing means which is disposed in the processing apparatus in FIG. 1;

FIG. 3 indicates a perspective view and an exploded perspective view illustrating a state where the processing means in FIG. 2 is used as cutting means;

FIG. 4 indicates a perspective view and an exploded perspective view illustrating a state where the processing means in FIG. 2 is used as polishing means;

FIG. 5 is a perspective view of a wafer W which is processed by the processing apparatus in FIG. 1;

FIG. 6 is a perspective view illustrating a wafer holding step according to the present embodiment;

FIG. 7A is a perspective view illustrating an embodiment of a chamfered portion removing step, FIG. 7B is a perspective view illustrating a wafer after the chamfered portion is removed in the chamfered portion removing step in FIG. 7A, and FIG. 7C is a partially enlarged cross-sectional view illustrating an outer periphery of the wafer in FIG. 7B; and

FIG. 8A is a perspective view illustrating an embodiment of a mirror surface processing step, and FIG. 8B is a partially enlarged cross-sectional view illustrating the outer periphery of the wafer in FIG. 8A.

### DESCRIPTION OF THE PREFERRED EMBODIMENTS

An embodiment of the method of processing a wafer based on the present invention will be described in detail with reference to the accompanying drawings. The method of processing a wafer based on the

present invention includes: a preparing step of preparing a processing apparatus; a wafer holding step of holding a wafer on a chuck table of the processing apparatus; a chamfered portion removing step of removing a chamfered portion of the wafer held on the chuck table; and a mirror surface processing step of polishing a cut surface of the wafer, which is held on the chuck table in the state after the chamfered portion is removed. In the following, each step will be described in detail.

### Preparation Step

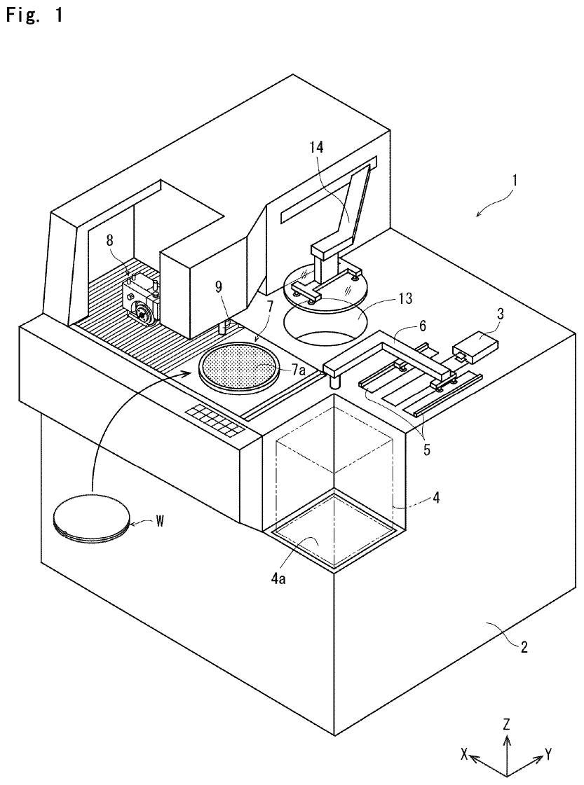

The preparation step is a step of preparing the processing apparatus, and the processing apparatus includes: a chuck table configured to hold a wafer (processing target object); cutting means including a rotatable cutting blade configured to cut a chamfered portion of the wafer held on the chuck table; and polishing means including a rotatable polishing blade configured to polish a surface from which the chamfered portion has been removed. The processing apparatus 1, which is prepared in the preparation step of this embodiment, will be described in detail with reference to FIG. 1.

The processing apparatus 1 illustrated in FIG. 1 has a housing 2, which is approximately rectangular parallelepiped-shaped, and includes: a cassette 4 which is placed on a cassette table 4a of the housing 2; a carry-in/out means 3 which carries out a wafer W (processing target object) from the cassette 4 to a temporary table 5; conveyance means 6 including a turning arm, which sucks the wafer W carried out onto the temporary table 5 and conveys the wafer W to a chuck table 7; processing means 8 which processes the wafer W held on the chuck table 7; imaging means 9 which captures an image of the wafer W held on the chuck table 7 to detect a region to be processed by the processing means 8; a cleaning apparatus 13 which cleans and dries the processed wafer W (details omitted); cleaning carry-out means 14 which carries out the wafer W from the carry in/out position where the chuck table 7 is positioned in FIG. 1, and conveys the wafer W to the cleaning apparatus 13; and control means, display means and the like (which are not illustrated in FIG. 1).

A suction chuck 7a constituting a holding surface of the chuck table 7 is an XY plane, which is specified by an X axis direction and a Y axis direction intersecting orthogonally with the X axis direction, and is substantially a horizonal plane. The suction chuck 7a is made of a material having permeability, and is connected to suction means (not illustrated), and negative pressure is applied to the suction chuck 7a by activating the suction means. The housing 2 encloses X axis feeding means which moves the chuck table 7 in the X axis direction, Y axis feeding means which moves the processing means 8 in the Y axis direction, Z axis feeding means which moves the processing means 8 in the Z axis direction (vertical direction), rotational-driving means which rotates the chuck table 7, and the like (none of these components are illustrated).

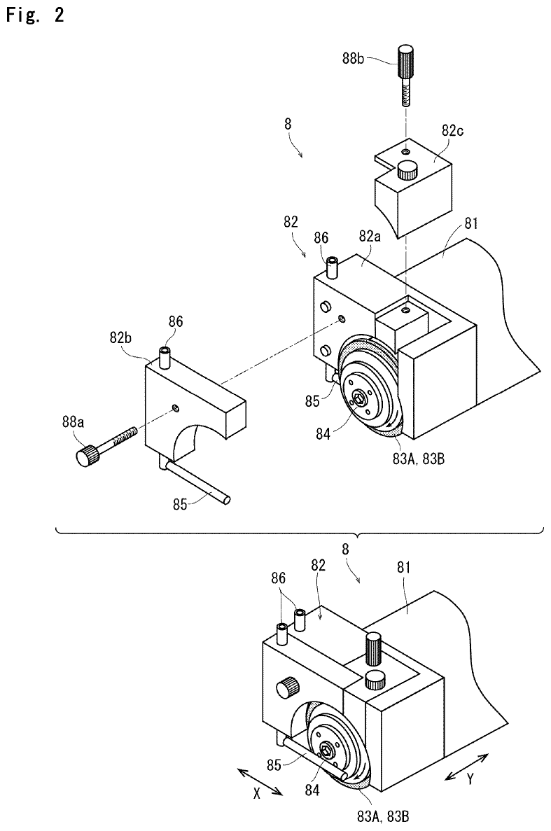

FIG. 2 is an enlarged view of a main part of the processing means 8 disposed in the processing apparatus 1 in FIG. 1, where an exploded perspective view thereof is indicated on the upper side. As illustrated here, the processing means 8 includes: a rotation shaft housing 81; a rotation shaft 84 which is rotatably held in the rotation shaft housing 81; a cutting blade 83A (or polishing blade 83B) which is fixed at a front end of the rotation shaft 84; and a blade cover 82, which is constituted of a plurality of members to protect the cutting blade 83A. In the blade cover 82, a pair of processing water supply nozzles 85 are disposed on each side of the cutting blade 83A, so as to supply processing water (e.g. pure water), which is introduced via processing water introducing portions 86 and 86 disposed on the blade cover 82, toward a cutting position. On the other end side of the rotation shaft housing 81, a rotational-driving source constituted of an electric motor (not illustrated) is housed, and the rotational-driving source rotates the cutting blade 83A by rotating the rotation shaft 84.

As illustrated in the exploded view indicated on the upper side in FIG. 2, the blade cover 82 includes: a fixing cover 82a which is fixed at the front end of the rotation shaft housing 81; a removable cover 82b which is attached to the front end of the fixing cover 82a using a screw 88a; and a blade detection block 82c which detects a state of the cutting blade 83A attached to an upper portion of the fixing cover 82a using a screw 88b.

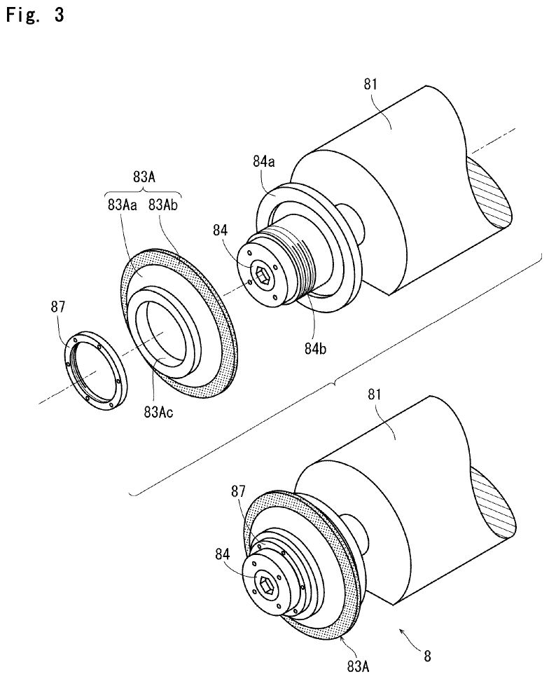

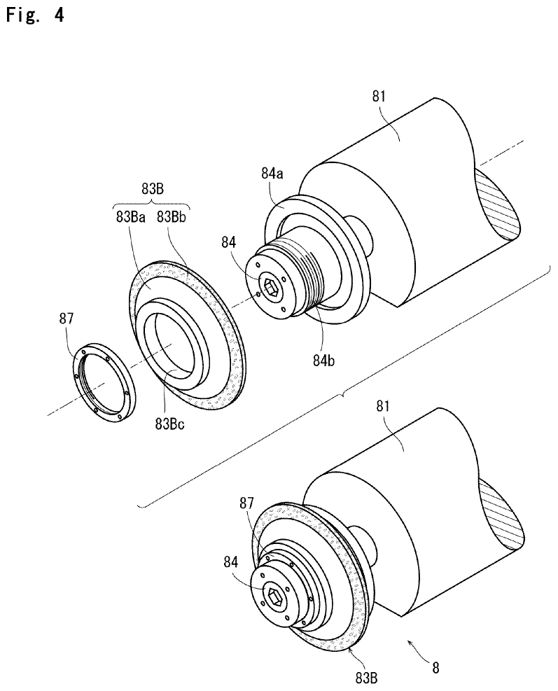

FIGS. 3 and 4 indicate a perspective view and an exploded view of the processing means 8 in a state where the abovementioned blade cover 82 is omitted for convenience of explanation. FIG. 3 is a case where the cutting blade 83A is attached to the rotation shaft 84, and FIG. 4 is a case where polishing blade 83B is attached to the rotation shaft 84.

As illustrated in FIG. 3, the processing means 8 includes: the rotation shaft 84 which is rotatably supported in the housing 81; the cutting blade 83A which is fixed to the front end of the rotation shaft 84; and a nut 87 to detachably fix the cutting blade 83A to the front end of the rotation shaft 84. On the outer peripheral surface of the rotation shaft 84 on the front end side, an annular-shaped flange 84a is disposed so as to protrude in the diameter direction. A male screw 84b is formed on the outer peripheral surface of the rotation shaft 84 further down on the front side of the flange 84a.

The cutting blade 83A illustrated in FIG. 3 includes: an annular-shaped circular base 83Aa formed of such metal material as aluminum alloy; and an annular-shaped cutting edge 83Ab which protrudes from one end of the outer peripheral surface of the circular base 83Aa in the diameter direction. At the center of the circular base 83Aa, a mounting port 83Ac, to which the front end of the rotation shaft 84 is inserted, is formed. The front end of the rotation shaft 84 is inserted into the mounting port 83Ac of the circular base 83Aa as illustrated, then the cutting blade 83A is contacted with the abovementioned flange 84a, and the nut 87 is fastened with the male screw 84b of the rotation shaft 84. Thereby the cutting blade 83A is fixed to the front end of the rotation shaft 84 in a state where it is held between the flange 84a and the nut 87.

As mentioned above, the cutting blade 83A is rotatably supported via the rotation shaft 84, and is used for cutting and removing the chamfered portion of the wafer W, as described later. The cutting edge 83Ab of the cutting blade 83A is a resin bond grinding wheel, for example, of which diameter is 50 mm and thickness is 3 mm. The cutting blade 83A is not limited to the resin bond grinding wheel, and may be a vitrified grinding wheel, or a metal bond grinding wheel, for example. The diameter and the thickness of the cutting blade 83A is also not limited to the above dimensions, and may be selected based on the diameter of the wafer W, the width of the chamfered portion 10C to be removed, and the like. As mentioned above, if the cutting blade 83A is attached to the rotation shaft 84, the processing means 8 functions as the cutting means of the present invention.

As illustrated in FIG. 4, the polishing blade 83B for polishing the cut surface, from which the chamfered portion of the wafer W has been removed, may be attached to the processing means 8 of this embodiment, instead of the abovementioned cutting blade 83A. The polishing blade 83B includes: an annular-shaped circular base 83Ba formed of such metal material as aluminum alloy; and an annular-shaped polishing pad 83Bb which protrudes from one end of the outer peripheral surface of the circular base 83Ba in the diameter direction. At the center of the circular base 83Ba, a mounting port 83Bc, to which the front end of the rotation shaft 84 is inserted, is formed. The front end of the rotation shaft 84 is inserted into the mounting port 83Bc of the circular base 83Ba as illustrated, then the polishing blade 83B is contacted with the abovementioned flange 84a, and the nut 87 is fastened with the male screw 84b of the rotation shaft 84. Thereby the polishing blade 83B is fixed to the front end of the rotation shaft 84 in a state where it is held between the flange 84a and the nut 87, and functions as the polishing means of the present invention. The polishing pad 83Bb of the polishing blade 83B is formed of porous urethane in which silica is mixed, for example, and of which diameter is 50 mm and thickness is 3 mm.

As mentioned above, the processing means 8 of this embodiment functions both as the cutting means and the polishing means of the present embodiment. Since the processing apparatus 1 includes this processing means 8, the processing apparatus 1 has the cutting means and the polishing means of the present invention.

The processing apparatus 1 of this embodiment has the abovementioned configuration, and the preparation step of this embodiment is completed by preparing the processing apparatus 1 as described above.

### Wafer Holding Step

After performing the preparation step described above, he wafer holding step of holding a wafer W (processing target object) on the chuck table 7 of the processing apparatus 1 is performed.

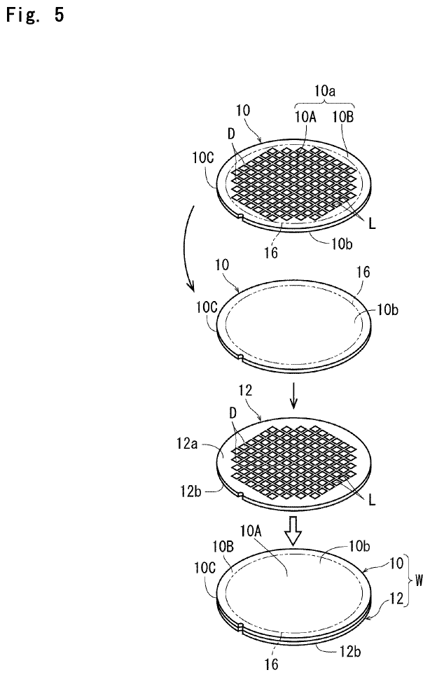

As illustrated in FIG. 5, the wafer W processed by the processing apparatus 1 of this embodiment is a bonded wafer generated by bonding a first wafer 10 and a second wafer 12. On a front surface 10a of the first wafer 10, a plurality of devices D are demarcated by division lines L. On the front surface 10a of the wafer 10, an effective region 10A including a device region, in which the plurality of devices D are formed, is formed on the center side, and an outer peripheral surplus region 10B, in which a chamfered portion 10C surrounding the effective region 10A is formed on the outer periphery, is disposed. In FIG. 5, an annular separation line 16 (two-dot chain line), to separate the effective region 10A and the outer peripheral surplus region 10B, is indicated, but this separation line 16 is for convenience of explanation, and is not actually drawn on the front surface 10a of the first wafer 10.

The second wafer 12, which is bonded with the first wafer 10, has approximately the same configuration as the first wafer 10, and as illustrated in FIG. 5, a plurality of devices D, which are demarcated by the division lines L, are formed on the front surface 12a thereof. As illustrated, the wafer W is generated by bonding the front surface 10a of the first wafer 10 with the front surface 12a of the second wafer 12, in a state where the rear surface 10b of the first wafer 10 faces upward and the front surface 10a thereof faces downward, using an appropriate bonding method. This bonding method to bond the first wafer 10 and the second wafer 12 is not especially limited, and for example, insulating films on the front surfaces are hydrophilized by surface activation treatment, and the front surface 10a of the first wafer 10 and the front surface 12a of the second wafer 12 are pressure-bonded such that a siloxane bond is formed on the bonding surface, or an appropriate adhesive may be used for the bonding.

The wafer processed by the method of processing a wafer according to this embodiment is not limited to the abovementioned wafer W, and may be, for example, a single wafer (a first wafer 10), as illustrated in FIG. 5.

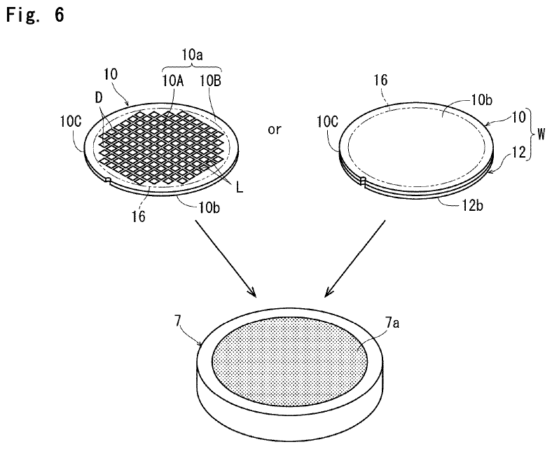

In the wafer holding step of this embodiment, the abovementioned carry-in/out means 3 is activated to convey the wafer W from the cassette 4 onto the temporary table 5, and to align the wafer W. Then the conveyance means 6 is activated to suck the wafer W on the temporary table 5, and, as illustrated in FIG. 6, convey the wafer W onto the suction chuck 7a of the chuck table 7 with the rear surface 12b of the second wafer 12 of the wafer W facing downward. Then the suction means (not illustrated) is activated to generate negative pressure on the suction chuck 7a to maintain the suction. If the processing target object is a single wafer (first wafer 10), the wafer is placed on the suction chuck 7a with the rear surface 10b side thereof facing downward, as illustrated on the left side of FIG. 6, and suction is maintained in this state. In the embodiment described below, it is assumed that the abovementioned wafer W, generated by bonding the first wafer 10 and the second wafer 12, is held on the chuck table 7.

### Chamfered Portion Removing Step

To perform the chamfered portion removing step described below, the abovementioned cutting blade 83A is attached to the rotation shaft 84 of the processing means 8, as described with reference to FIG. 3, so that the processing means 8 is used as the cutting means.

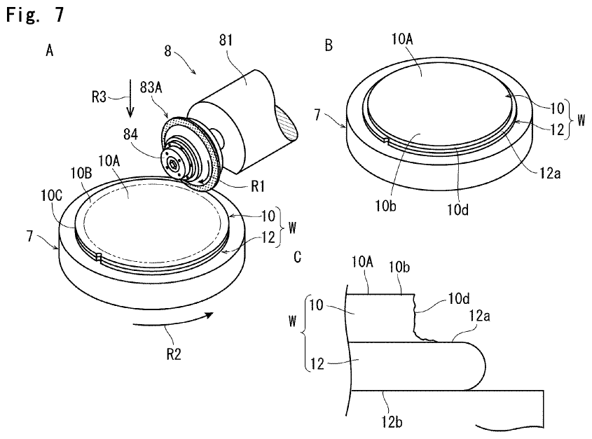

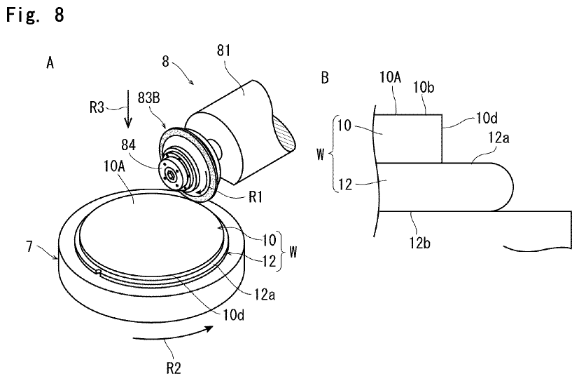

After performing the abovementioned wafer holding step, the wafer W is positioned immediately below the imaging means 9 by the X axis feeding means (not illustrated), and the image of the wafer W is captured. Then alignment is performed to detect the outer periphery of the wafer W, and position information on the chamfered portion 10C, to be removed from the wafer W, is detected. Then based on the position information on the chamfered portion 10C to be removed, detected by the imaging means 9, the abovementioned X axis feeding means and the Y axis feeding means are activated, so that the cutting blade 83A is positioned at the outer peripheral surplus region 10B of the first wafer 10 of the wafer W held on the chuck table 7, as illustrated in FIG. 7A. In the processing means 8 illustrated in FIG. 7 and FIG. 8 (described later), the blade cover 82 is omitted for convenience of explanation. Then the cutting blade 83A is rotated at a predetermined rotation speed (e.g. 30000 rpm) in the direction indicated by the arrow R1, and the chuck table 7 is rotated at a predetermined rotation speed (e.g. 1 rpm) in the direction indicated by the arrow R2.

Then processing water (e.g. pure water) is supplied from the abovementioned processing water supply nozzle 85, to the cutting region, and the Z axis feeding means is activated, whereby the processing means 8 performs cut and feed in the direction of the arrow R3 in FIG. 7A, so as to cut to a thickness of the first wafer 10. Thereby the chamfered portion 10C of the first wafer 10 is removed in an annular shape, as illustrated in FIG. 7B, and thus the chamfered portion removing step is completed. Here in the case of removing the chamfered portion 10C by the cutting blade 83A, a cut surface 10d, from which the chamfered portion 10C of the firs wafer 10 has been removed, becomes a rough surface, as illustrated in FIG. 7C, and a part of the chamfered portion 10C of the first wafer 10 remains. Further, the cut and feed amount is set such that the second wafer 12 is not cut, hence a part of the first wafer 10 remains on the front surface 12a of the second wafer 12, with which the chamfered portion 10C of the first wafer 10 was bonded. Therefore after the chamfered portion removing step is performed on the wafer W like this, the abovementioned cleaning carry-out means 14 is activated, so as to convey the wafer W held on the chuck table 7 to the cleaning apparatus 13, and cleaning and drying of the wafer W is performed. Then the abovementioned conveyance means 6 and the carry-in/out means 3 are activated, so that the wafer W, from which the chamfered portion 10C has been removed, is housed in a predetermined position of the cassette 4. In the chamfered portion removing step of this embodiment, the chamfered portion removing step is performed for all the wafers W housed in the cassette 4, then the mirror surface processing step described below is performed on the wafer W after the chamfered portion is removed.

### Mirror Surface Processing Step

To perform the mirror surface processing step of this embodiment, the polishing blade 83B, instead of the cutting blade 83A, is attached to the processing means 8 as described with reference to FIG. 4, so that the processing means 8 is used as the polishing means. Then the wafer holding step is performed so that the wafer W, from which the chamfered portion 10C of the first wafer 10 has been removed in the abovementioned chamfered portion removing step, is held on the chuck table 7. The wafer holding step is performed in the same procedure as the abovementioned wafer holding step performed before the chamfered portion removing step, hence detailed description is omitted. Then alignment is performed by the imaging means 9, to detect the position of the outer periphery of the first wafer 10 from which the chamfered portion 10C has been removed, where the cut surface 10d is formed.

Then based on the position information on the outer periphery of the first wafer 10 where the cut surface 10d is formed, the abovementioned X axis feeding means and the Y axis feeding means are activated, so that the polishing blade 83B is positioned above the first wafer 10 of the wafer W held on the chuck table 7. Then as illustrated in FIG. 8A, the polishing blade 83B is rotated in a direction indicated by the arrow R1 at a predetermined rotation speed (e.g. 3000 rpm), which is slower than the time of performing the chamfered portion removing step, and the chuck table 7 is rotated at a predetermined rotation speed (e.g. 1 rpm) in a direction indicated by the arrow R2.

Here slurry for polishing, instead of the abovementioned processing water, is supplied from the processing water supply nozzle 85 to the polishing region, and the Z axis feeding means (not illustrated) is activated to lower the processing means 8 in the direction indicated by the arrow R3, so that the polishing blade 83B contacts and polishes a front surface 12a of the second wafer 12 from which the cut surface 10d and the chamfered portion 10C of the first wafer 10 have been removed. Then the abovementioned polishing is performed for a predetermined time, whereby the rough surface of the cut surface 10d of the first wafer 10 is smoothed, as illustrated in FIG. 8B, and the mirror surface processing, to remove the remaining portion on the front surface 12a of the second wafer 12, is performed, and thus the mirror surface processing step of this embodiment is completed. Depending on the type of the polishing pad 83Bb constituting the polishing blade 83B (e.g. fine grains are mixed in), the processing water (pure water) may be directly supplied from the processing water supply nozzle 85, instead of supplying slurry, to the polishing region. In the case of supplying slurry for polishing when the abovementioned polishing processing is performed, a dedicated nozzle, to supply the slurry for polishing the polishing region, may be disposed instead of the processing water supply nozzle 85. Once this mirror surface processing step is performed, the abovementioned cleaning carry-out means 14 is activated, so as to convey the wafer W held on the chuck table 7 to the cleaning apparatus 13, and cleaning and drying the wafer W is performed. Then the abovementioned conveyance means 6 and the carry-in/out means 3 are activated, so that the wafer W, on which the mirror surface processing has been performed, is housed in a predetermined position in the cassette 4, thereby the method of processing of the wafer according to this embodiment is completed.

According to the embodiment described above, the chamfered portion 10C is removed from the outer periphery of the wafer W by the cutting means, then the mirror surface processing is performed on the cut surface 10d by the polishing means, whereby the remaining portions are completely removed. Therefore such problems where the remaining portion falls and becomes a source of contamination, or the remaining portion causes chipping of the device chips when the wafer W is diced into individual device chips, can be solved.

The wafer processed in the embodiment described above is the wafer W generated by bonding the first wafer 10 and the second wafer 12, but the wafer processed by the method of processing a wafer according to the present embodiment is not limited to the bonded wafer, and may be a single wafer (e.g. first wafer 10 only).

The embodiment described above is configured such that the cutting blade 83A or the polishing blade 83B is selectively attached to the processing means 8 disposed in the processing apparatus 1, which is prepared in the preparation step, so that one processing means 8 can be used as a cutting means and as a polishing means. However the processing apparatus 1 may include both the cutting means and polishing means, so that the chamfered portion removing step and the mirror surface processing step can be performed continuously.

### REFERENCE SIGNS LIST

1 Processing apparatus
2 Housing
3 Carry-in/out means
4 Cassette
5 Temporary table
6 Conveyance means
7 Chuck table
7a Suction chuck
8 Processing means
81 Rotation shaft housing
82 Blade cover
83A Cutting blade
83B Polishing blade
84 Rotation shaft
84a Flange
84b Male screw
85 Processing water supply nozzle
86 Processing water introducing portion
87 Nut
9 Imaging means
10 First wafer
10a Front surface
10b Rear surface
10d Cut surface
10A Effective region
10B Outer peripheral surplus region
10C Chamfered portion
12 Second wafer
12a Front surface
12b Rear surface
13 Cleaning apparatus
14 Cleaning carry-out means
W Wafer

What is claimed is:

1. A method of processing a wafer having an effective region including a device region, in which a plurality of devices are demarcated by division lines, and an outer peripheral surplus region, in which a chamfered portion surrounding the effective region is formed,
the method comprising:
a preparation step of preparing a processing apparatus, which includes a chuck table configured to hold a wafer, cutting means including a rotatable cutting blade configured to cut the chamfered portion of the wafer held on the chuck table, and polishing means including a rotatable polishing blade configured to polish a surface from which the chamfered portion has been removed;
a wafer holding step of holding the wafer on the chuck table;
a chamfered portion removing step of removing the chamfered portion by rotating the chuck table, with the cutting blade being positioned on the outer peripheral surplus region of the wafer that is held on the chuck table, and with the cutting blade rotating; and
a mirror surface processing step of polishing a cut surface, from which the chamfered portion has been removed, into a mirror surface by rotating the chuck table, with the polishing blade being positioned on the outer periphery of the wafer that is held on the chuck table in a state where the chamfered portion has been removed, and with the polishing blade rotating.

2. The method of processing a wafer of claim 1, wherein in the mirror surface processing step, water or slurry is supplied to polish the cut surface.

3. The method of processing a wafer of claim 1, wherein
the wafer is a bonded wafer generated by bonding a surface, on which the effective region of a first wafer has been formed, with a second wafer, and
in the wafer holding step, the second wafer side is held on the chuck table, and
the chamfered portion removing step and the mirror surface processing step are performed on the first wafer of the wafer held on the chuck table.

4. The method of processing a wafer of claim 2, wherein
the wafer is a bonded wafer generated by bonding a surface, on which the effective region of a first wafer has been formed, with a second wafer, and
in the wafer holding step, the second wafer side is held on the chuck table, and
the chamfered portion removing step and the mirror surface processing step are performed on the first wafer of the wafer held on the chuck table.
